(19) United States
(12) Patent Application Publication
(10) Pub. No.: US 2024/0232296 A9
(43) Pub. Date: Jul. 11, 2024

(54) DEEP LEARNING-BASED METHOD FOR FUSING MULTI-SOURCE URBAN ENERGY DATA AND STORAGE MEDIUM

(71) Applicant: STATE GRID JIANGSU ELECTRIC POWER CO., LTD NANJING POWER SUPPLY COMPANY, Jiangsu (CN)

(72) Inventors: Zhengyi ZHU, Jiangsu (CN); Honghua XU, Jiangsu (CN); Weiya ZHANG, Jiangsu (CN); Long LIANG, Jiangsu (CN); Jinjie MA, Jiangsu (CN); Hengjun ZHOU, Jiangsu (CN); Wendi WANG, Jiangsu (CN); Xin QIAN, Jiangsu (CN); Linqing YANG, Jiangsu (CN)

(73) Assignee: STATE GRID JIANGSU ELECTRIC POWER CO., LTD NANJING POWER SUPPLY COMPANY, Jiangsu (CN)

(21) Appl. No.: 18/074,510

(22) Filed: Dec. 4, 2022

(30) Foreign Application Priority Data
Oct. 20, 2022 (CN) 202211289031.4

(51) Int. Cl. G06F 18/25

(52) U.S. Cl. CPC G06F 18/256; G06F 18/253; G06Q 50/06

(57) ABSTRACT

A deep learning-based method for fusing multi-source urban energy data and a storage medium are provided to perform data fusion on multi-source urban energy data found in big data and perform multi-scale and multimodal information fusion by using a cross-modal transformer, thereby implementing cross-modal mutual fusion of multi-source heterogeneous types of data to obtain a fused feature for prediction of a quantity of energy that will be used in the future and a quantity of energy that needs to be produced. The present disclosure proposes a multi-scale cooperative multimodal transformer architecture to enhance an effect of representation learned from an unaligned multimodal sequence. Not only there is a higher degree of correlation in multi-source urban energy data fusion, but also a system becomes more lightweight.

### CROSS-REFERENCE TO RELATED APPLICATION

This application claims the priority benefit of China application serial no. 202211289031.4 filed on Oct. 20, 2022, The entirety of the above-mentioned patent application is hereby incorporated by reference herein and made a part of this specification.

### BACKGROUND

### Technical Field

The present invention relates to the technical field of computers, relates to electrical power system data processing, and provides a deep learning-based method for fusing multi-source urban energy data and a storage medium.

### Description of Related Art

In an era of big data, there is an increasingly wider range of sources of urban energy data, and data types are also increasingly diversified. However, with the 5Vs of big data, namely, volume, variety, value, veracity, and velocity, it is difficult to adequately dig up implicit information in urban energy big data. Therefore, an effective means is highly needed to fuse global multi-source heterogeneous urban energy data and dig up valuable information for use. The data fusion technology is widely used as an important data processing means. In various fields, the data fusion technology effectively improves the capabilities of man to process and use industrial big data. By using the data fusion technology, a huge amount of high-dimensional, multi-source heterogeneous, and noisy industrial data goes through denoising integrated modeling, and multi-scale classification to provide reliable data resource for subsequent correlation analysis, performance prediction, and decision-making optimization. Therefore, the data fusion technology greatly supports the development of the fields to which the technology is applied.

Commonly used data fusion methods include a probability-based fusion method, a Dempster-Shafer evidence theory—based fusion method, a knowledge-based fusion method, etc. The probability-based fusion method includes Bayesian reasoning, a Kalman filtering model, a Markov model. The key mathematical theory behind such fusion methods is Bayesian reasoning in which a probability distribution and a probability density function are introduced to indicate a dependence between random variables to establish a relationship between different data sets. The evidence theory—based fusion method mainly includes the D-S evidence theory in which a confidential level and a reasonable degree are introduced to indicate uncertainty of data, the reasoning is performed dynamically, and data fusion is performed by using a specified rule of fusion. As the development of Bayesian reasoning, the D-S theory, compared with Bayesian reasoning, has an advantage of not requiring a prior probability of data. The knowledge-based fusion method includes a vector machine, clustering, and another method. In such a method, a large amount of useful knowledge information is considered to be contained in data, and the key of such a method is to find out the knowledge contained in the data and measure the correlation and similarity between the knowledge.

However, the foregoing common data fusion methods have many disadvantages for fusing big data. For example, the probability-based fusion method has drawbacks to obtaining a prior probability and processing complicated high-dimensional data; the evidence theory-based fusion method has drawbacks to estimating a quality function; and the knowledge-based fusion method is sensitive to missing data and noisy data. With the development of computation hardware and data processing technologies in computers, a computation capability of a computing device is not an obstacle to deep learning any longer. This has brought new development opportunities to use deep learning in data fusion. Deep learning can perform self-learning based on training data and does not require implementation of particular programming to solve each problem. A deep learning model is intended to model data to obtain an in-depth correlative relationship in the data and establish a knowledge frame, such that the model is finally used to predict, classify, extract a feature, and so forth. In recent years, researchers have tried to use deep learning in data fusion and hope to enhance the performance of a fusion algorithm in processing big data. There are still some difficulties in using a deep learning-based data fusion method, especially for the heterogeneity of data that is to be fused, while heterogeneity is a key feature of big data. At present, urban energy big data is from various areas, and there are not only structured data sheets, but there are more non structured data, for example, texts, images, and audio. The heterogeneity exists between these multi-source data indicates a difference between features of these data. How to correlate, cross heterogeneous data, and finally obtain a correlative relationship between the data is significant for studying fusion of current urban energy data.

### SUMMARY

The purpose of the present invention is to provide a transformer-based method for fusing multi-source urban energy data that can used to perform data fusion on different types of urban energy data from various industries and facilitate the development of a smart urban energy system, efficient management of urban energy, and revolutionary development of the urban energy industry.

The technical solution of the present invention is a deep learning-based method for fusing multi-source urban energy data. The method includes the following steps:

S1, converting obtained multi-source urban energy data into a multimodal input sequence, where three types of heterogeneous data of the urban energy data include a text X_{W}∈R^{T}^{_{W}}^{×D}^{_{W}}, an image X₁∈R^{T}^{₁}^{×D}^{₁}, and audio X_{A}∈R^{T}^{_{A}}^{×D}^{_{A}};

S2, performing one-dimensional time convolution once on the data in the multimodal input sequence in S1 to obtain time information and obtain an urban energy data feature with the time information;

S3, performing positional encoding (PE) on an output in S2 to ensure that the time information is retained in subsequent calculation;

S4, performing multi-scale and multimodal information fusion on an output in S3 by using a cross-modal transformer to implement cross-modal mutual fusion of the three types of heterogeneous data that is represented by [Z_{I→W}^{[D]}, Z_{A→W}^{[D]}]∈R^{T}^{_{W}}^{×2d}, [Z_{W→I}^{[D]}, Z_{A→I}^{[D]}]∈R^{T}^{₁}^{×2d}, and [Z_{I→A}^{[D]}, Z_{W→A}^{[D]}]∈R^{T}^{_{A}}^{×2d}; and

S5, putting [Z_{I→W}^{[D]}, Z_{A→W}^{[D]}]∈R^{T}^{_{W}}^{×2d}, [Z_{W→I}^{[D]}, Z_{A→I}^{[D]}]∈R^{T}^{₁}^{×2d}, and [Z_{I→A}^{[D]}, Z_{W→A}^{[D]}]∈R^{T}^{_{A}}^{×2}d pairwise into three transformer networks with self-attention for self-attention calculation, to obtain a fused feature of the multi-source urban energy data, where the fused feature is input to a deep learning-based prediction model and used to predict a quantity of energy that will be used in the future and a quantity of energy that needs to be produced.

The present invention further provides a computer-readable storage medium. The computer-readable storage medium stores a computer program, and when the computer program is executed by a processor, the steps of the foregoing method are implemented.

Compared with a conventional technology, the present invention has the following beneficial effects:

In the present invention, a manner of fusing multi-source data that is more applicable to urban energy data is proposed. Unlike existing transformer-based technologies, in this manner, multi-scale and multimodal information fusion is performed on an output in S3 by using a cross-modal transformer. Especially the independently designed MCMulT module can lay more emphasis on data fusion between modes that needs to be fused in a prediction result, thereby improving the quality of representation learned from an unaligned multimodal sequence to enhance the applicability for extensive data fusion. Both performance and efficiency are taken into account, and urban energy heterogeneous data in different dimensions and different modes can be fused, so that the problem of having difficulty in fusing heterogeneous data is solved. As the problem of heterogeneity of urban energy data is solved, a high dimension due to direct tensor multiplication for fusion is prevented, and the calculation complexity for an urban energy big data platform is reduced.

### BRIEF DESCRIPTION OF THE DRAWINGS

FIG. 1 is a schematic flowchart of a method for fusing global multi-source urban energy data according to the present invention.

FIG. 2 is a schematic diagram of a structure of a multi-scale multimodal transformer architecture module according to the present invention.

FIG. 3A and FIG. 3B are schematic diagrams of structures of two types of cross-modal units according to the present invention, where FIG. 3A is a CT block, and FIG. 3B is a MACT block.

### DESCRIPTION OF THE EMBODIMENTS

The technical solution of the present invention is clearly and completely described below in conjunction with the accompanying drawings. Obviously, the described embodiments are merely a part of the embodiments of the present invention and not all the embodiments. Based on the embodiments of the present invention, all other embodiments obtained by those ordinarily skilled in the art without paying creative work shall fall within the protection scope of the present invention.

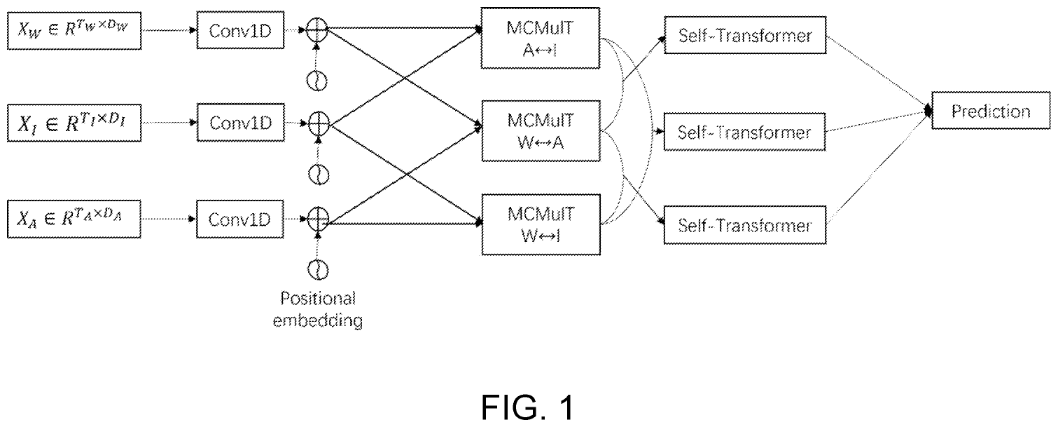

As shown in FIG. 1, this embodiment provides a transformer-based method for fusing global multi-source urban energy data, and proposes a multi-scale cooperative multimodal transformer architecture (Multi-scale Collaboration Multimodal Transformer, MCMulT), to enhance an effect of representation learned from an unaligned multimodal sequence. Not only there is a higher degree of correlation in multi-source urban energy data fusion, but also a system becomes more lightweight. By using the architecture, an urban data fused feature is output finally, and the feature is put into a deep learning prediction model to predict a quantity of energy that will be used in the future and a quantity of energy that needs to be produced, and another function, thereby facilitating building a smart decision-making functional module on an urban energy big data platform.

The method of the present invention includes the following steps:

S1: Sources of the global multi-source urban energy data include the water, coal, electricity, heating power, and oil industries. Textual data is sourced in production data, management data, and marketing data that are found in urban energy big data from various energy industries, and data about consumption of various types of energy; image data is sourced in geographic information system (GIS) information and a meteorogram that are found in energy big data from coal, oil, and electricity industries, traffic flow image information about energy consumption of oil and electricity, and the like. Audio data is sourced in energy use-related audio report information obtained from various energy industries through Internet big data mining, interview audio information related to energy use in various industries, and audio data of an interview with people working in various energy industries about a usage amount of a type of energy in the future. The global multi-source urban energy data that is found includes, but is not limited to, the foregoing data. Global multi-source urban energy data in each energy industry that is found is separately converted to a multimodal input sequence X, and three types of heterogeneous data, that is, a text X_{W}∈R^{T}^{_{W}}^{×D}^{_{W}}, an image X₁∈R^{T}^{₁}^{×D}^{₁}, and audio X_{A}∈R^{T}^{_{A}}^{×D}^{_{A}}, of the global urban energy data are extracted, where the subscripted “I” means “image”, “W” means “text”, “A” means “audio” X_{W}∈R^{T}^{_{W}}^{×D}^{_{W}}, w means text sequence X_{W} belonging to T_{W}×D_{W} dimension real number set, X₁∈R^{T}^{₁}^{×D}^{₁} and X_{A}∈R^{T}^{_{A}}^{×D}^{_{A}} are similar. The final purpose of the method of the present invention is to fuse the foregoing heterogeneous data to obtain a feature for facilitating subsequent prediction of a usage amount of a type of energy in the future and other information by using a deep learning prediction module, thereby helping build an urban energy big data platform. The method for fusing multi-source urban energy data proposed above is specifically described below.

S2: One-dimensional time convolution is performed once separately on the urban energy data in S1 to obtain time information and obtain an urban energy data feature with the time information, where a manner of the time convolution is as follows:

X′_{α}=Conv1D(X_{α},k_{α})∈R^{T}^{_{α}}^{×d} (1)

where X_{α} represents the data in the multimodal input sequence, k_{α} represents a size of a convolution kernel in a corresponding mode α, and d represents a dimension of the feature. S3: Positional encoding (PE) is performed on an output in S2 to ensure that the time information is retained in subsequent calculation; and

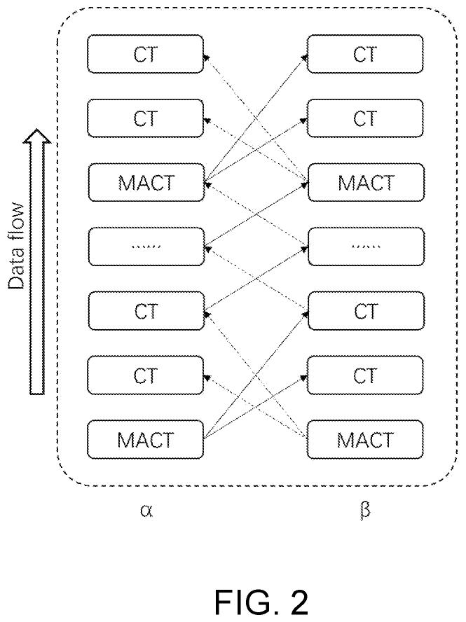

S4: Multi-scale and multimodal information fusion is performed on an output in S3 by using a cross-modal transformer to implement cross-modal mutual fusion of the three types of heterogeneous data. In the present invention, the multi-scale cooperative multimodal transformer (MCMulT) architecture is built to implement multimodal and multi-scale information fusion. The MCMulT module focuses more on directional cross-modal interactions between modes, and the target mode shown in the multi-scale mechanism forms a multi-scale feature of the mode by fusing the directional cross-modal interactions. Each type of integration is implemented by gathering a multi-scale feature of a source mode. As shown in FIG. 2, a MCMulT network is divided into several densely connected cross-modal transformer blocks MCTBs, and the blocks include two types of cross-modal units: a multi-scale attention cross-modal MACT block and a cross-modal CT block, where a MACT block in one dimension and two adjacent CT blocks in another dimension form a cross-modal transformer block. For a target mode α and a source mode β, a global interaction of the MCMulT is performed by a plurality of MACT blocks, where an input of a MCTB in the target mode is from outputs of a plurality of MCTBs in the source mode. To keep an interaction with windowing, a local interaction is formed between a MCTB in the target mode and a MCTB in the source mode that are at a same scale, a local interaction of the MCMulT is performed by a CT block, where an input of the CT block includes a previous-layer output in the target mode and the first layer output of a MCTB in a same scale in the source mode. It should be noted that the local interaction is represented using only a single scale in the source mode, and such a mechanism of blocking reduces a quantity of parameters.

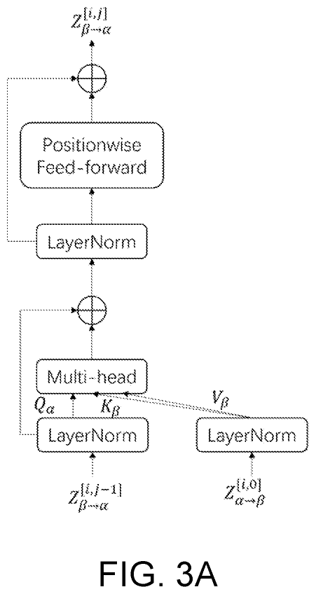

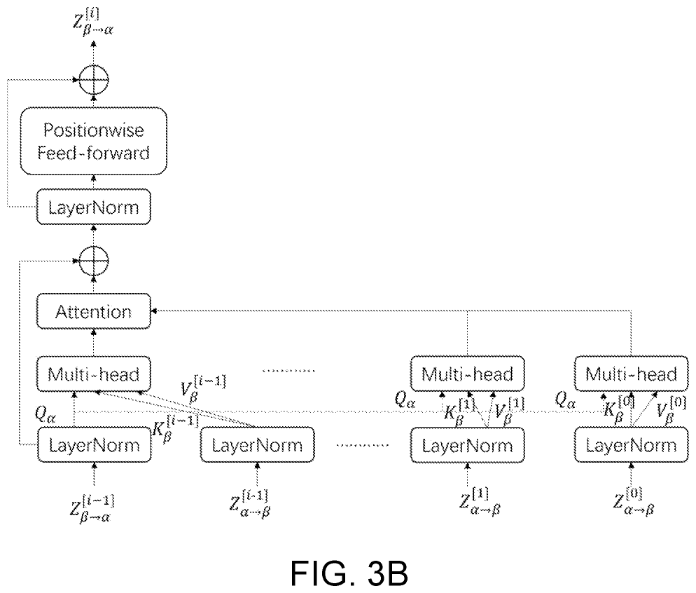

A core unit of the transformer block is a MACT block that includes three subnetwork layers: a multi-scale multi-head cross-modal layer, a multi-scale attention layer, and a position-wise feedforward layer. The CT block is used for only the representation of a single scale in the source mode and no attention processing, and can be considered a simpler MACT block. As shown in FIG. 3, (a) in FIG. 3 is a CT block, and (b) in FIG. 3 is a MACT block.

For the target mode α and the source mode β that are to be fused, Z_{α}∈R^{T}^{_{α}}^{×d}^{_{α}} and Z_{β}∈R^{T}^{_{β}}^{×d}^{_{β}} are used to represent features from two modal sequences respectively, and the multi-scale cross-modal layer of the cross-modal transformer block is parallel by using a plurality of multi-head layers, to combine a plurality of directional pairwise cross-modal interactions between the target mode α and the source mode β, which is as follows:

$$C {M}_{α \to β} ( {Z}_{α} , {Z}_{β} ) = softmax ( \frac{{Z}_{α} {W}_{{Q}_{α}} {W}_{{K}_{β}}^{T} {Z}_{β}^{T}}{\sqrt{{d}_{k}}} ) {Z}_{β} {W}_{{V}_{β}} \qquad ( 2 )$$

The foregoing equation is an expression of multi-head, both the MACT and the CT include multi-head, showing multi-scale crossing, where W_{Q}_{_{α}}, W_{K}_{_{β}}, and W_{V}_{_{β}} are weight parameters corresponding to a mode having a Q (query), K (key), and V (value), and \sqrt{dₖ} is a scaling factor. When the mode α forms a i^{th} layer of cross-modal interaction from the mode β, H^{[i]} represents a set of multi-scale cross-modal interactions between the modes a and a that is as follows:

H^{[i]}={CM_{β→α}(Z_{β→α}^{[i-1]},Z_{α→β}^{j})}j=0,1, . . . ,i−1 (3)

Z_{α→β}^{[0]}=Z_{β}^{[0]} (4)

where Z_{β}^{[0]} is a low-level feature of the mode β. Z_{β→α}^{[i]} is output finally through preliminary fusion in a corresponding feedforward layer:

P_{β→α}^{[i]}=f_{θ}(LN(A_{β→α}^{[i]}+LN(Z_{β→α}^{[i-1]}))) (5)

Z_{β→α}^{[i]}={A_{β→α}^{[i]}+LN(Z_{β→α}^{[i-1]})}+P_{β→α}^{[i]} (6)

Cross-modal mutual fusion of the three types of heterogeneous data is implemented according to Z_{β→α}^{[i]} to obtain fusion results [Z_{I→W}^{[D]}, Z_{A→W}^{[D]}]∈R^{T}^{_{W}}^{×2d}, [Z_{W→I}^{[D]}, Z_{A→I}^{[D]}]∈R^{T}^{₁}^{×2d}, and [Z_{I→A}^{[D]}, Z_{W→A}^{[D]}]∈R^{T}^{_{A}}^{×2d}, where the subscripted “I” means “image”, “W” means “text”, “A” means “audio”, and “[D]” means a D^{th} layer of cross-modal interaction.

S5: [Z_{I→W}^{[D]}, Z_{A→W}^{[D]}]∈R^{T}^{_{W}}^{×2d}, [Z_{W→I}^{[D]}, Z_{A→I}^{[D]}]∈R^{T}^{₁}^{×2d}, and [Z_{I→A}^{[D]}, Z_{W→A}^{[D]}]∈R^{T}^{_{A}}^{×2}d are put into three transformer networks with self-attention for self-attention calculation for self-attention calculation, and with mutual fusion of each mode in S4, a fused feature of the multi-source urban energy data is obtained finally, where the finally obtained fused feature after the fusion is put into a deep learning-based prediction model, to implement prediction of a quantity of energy that will be used in the future and a quantity of energy that needs to be produced and another function, thereby facilitating refined management of urban energy and science-based demand-side management to help build a smart decision-making functional module on an urban energy big data platform.

Those skilled in the art should understand that the embodiments of the present invention can be provided as a method, a system, or a computer program product. Therefore, the present invention may use complete hardware embodiments or complete software embodiments, or have a form combining the embodiments in aspects of software and hardware. Further, the present invention may be in a form of a computer program product that is executed on one or more computer-usable storage media including computer-usable program code.

These computer program instructions may also be stored in a computer-readable memory that can instruct the computer or any other programmable data processing device to work in a specific manner, so that the instructions stored in the computer-readable memory generate an artifact that includes an instruction apparatus. The instruction apparatus implements a function specified in one or more procedures of the flowchart and/or in one or more blocks of the block diagram.

These computer program instructions can be loaded to a computer or another programmable data processing device for the computer or the another programmable device to execute a series of operation steps to generate processing implemented by the computer, so that an step for implementing functions specified in one or more procedures of a flowchart and/or one or more blocks of a block diagram is provided by using the instructions executed on the computer or the another programmable device.

What is claimed is:

1. A deep learning-based method for fusing multi-source urban energy data, comprising the following steps:
S1, converting obtained multi-source urban energy data into a multimodal input sequence, wherein three types of heterogeneous data of urban energy data comprise a text X_{W}∈R^{T}^{_{W}}^{×D}^{_{W}}, an image X₁∈R^{T}^{_{1×}}^{D}^{₁}, and audio X_{A}∈R^{T}^{_{A}}^{×D}^{_{A}};
S2, performing a one-dimensional time convolution once on data in the multimodal input sequence in the step S1 to obtain time information and obtain an urban energy data feature with the time information;
S3, performing positional encoding (PE) on an output in the step S2 to ensure that the time information is retained in a subsequent calculation;
S4, performing a multi-scale and multimodal information fusion on an output in the step S3 by using a cross-modal transformer to implement a cross-modal mutual fusion of the three types of the heterogeneous data that is represented by [Z_{I→W}^{[D]}, Z_{A→W}^{[D]}]∈R^{T}^{_{W}}^{×2d}, [Z_{W→I}^{[D]}, Z_{A→I}^{[D]}]∈R^{T}^{₁}^{×2d}, and [Z_{I→A}^{[D]}, Z_{W→A}^{[D]}]∈R^{T}^{_{A}}^{×2d}; and
S5, putting [Z_{I→W}^{[D]}, Z_{A→W}^{[D]}]∈R^{T}^{_{W}}^{×2d}, [Z_{W→I}^{[D]}, Z_{A→I}^{[D]}]∈R^{T}^{₁}^{×2d}, and [Z_{I→A}^{[D]}, Z_{W→A}^{[D]}]∈R^{T}^{_{A}}^{×2}d pairwise into three transformer networks with a self-attention for a self-attention calculation, to obtain a fused feature of the multi-source urban energy data, wherein the fused feature is an input to a deep learning-based prediction model and used to predict a quantity of energy that will be used in the future and the quantity of the energy that needs to be produced.

2. The deep learning-based method for the fusing multi-source urban energy data according to claim 1, wherein in the step S1, sources of the multi-source urban energy data comprise water, coal, electricity, heating power, and oil industries, wherein textual data is sourced in production data, management data, and marketing data that are found in energy big data from various energy industries, and data about a consumption of various types of the energy; image data is sourced in geographic information system (GIS) information and a meteorogram that are found in the energy big data from the coal, the oil, and the electricity industries, and traffic flow image information about an energy consumption of the oil and the electricity; and audio data is sourced in energy use-related audio report information obtained from the various energy industries through Internet big data mining, interview audio information related to the energy use in various industries, and the audio data of an interview with people working in the various energy industries about a usage amount of a type of the energy in the future.

3. The deep learning-based method for fusing multi-source urban energy data according to claim 1, wherein in the step S3, a manner of a time convolution is as follows:
X′_{α}=Conv1D(X_{α},k_{α})∈R^{T}^{_{α}}^{×d} (1)
wherein X_{α} represents the data in the multimodal input sequence, k_{α} represents a size of a convolution kernel in a corresponding mode α, Conv1D represents the one-dimensional time convolution, and d represents a dimension of a feature.

4. The deep learning-based method for fusing multi-source urban energy data according to claim 1, wherein in the step S4, a multi-scale cooperative multimodal transformer (MCMulT) architecture is built to implement a multimodal and multi-scale information fusion, wherein a MCMulT network is divided into several connected cross-modal transformer blocks (MCTBs), and blocks comprise two types of cross-modal units, which are a multi-scale attention cross-modal (MACT) block and a cross-modal (CT) block, wherein a MACT block in one dimension and two adjacent CT blocks in another dimension form a cross-modal transformer block; and for a target mode and a source mode, a global interaction of the MCMulT is performed by a plurality of MACT blocks, wherein an input of a MCTB in the target mode is from outputs of a plurality of MCTBs in the source mode, and to keep an interaction with windowing, a local interaction is formed between the MCTB in the target mode and the MCTB in the source mode that are at a same scale, a local interaction of the MCMulT is performed by the CT block, wherein an input of the CT block comprises a previous-layer output in the target mode and a first layer output of the MCTB in a same scale in the source mode, and the local interaction is represented using only a single scale in the source mode; wherein, the MACT block comprises three subnetwork layers, which are a multi-scale multi-head cross-modal layer, a multi-scale attention layer, and a position-wise feedforward layer, and the CT block is used for only a representation of a single scale in the source mode.

5. The deep learning-based method for fusing multi-source urban energy data according to claim 4, wherein for the target mode α and the source mode β that are to be fused, Z_{α}∈R^{T}^{_{α}}^{×d}^{_{α}} and Z_{β}∈R^{T}^{_{β}}^{×d}^{_{β}} are used to represent features from two modal sequences respectively, and the multi-scale multi-head cross-modal layer is used to combine directional pairwise cross-modal interactions between the target mode α and the source mode β:
$$C {M}_{α \to β} ( {Z}_{α} , {Z}_{β} ) = softmax ( \frac{{Z}_{α} {W}_{{Q}_{α}} {W}_{{K}_{β}}^{T} {Z}_{β}^{T}}{\sqrt{{d}_{k}}} ) {Z}_{β} {W}_{{V}_{β}} \qquad ( 2 )$$
wherein W_{Q}_{_{α}}, W_{K}_{_{β}} and W_{V}_{_{β}} are weight parameters, and when the target mode α forms a i^{th} layer of a cross-modal interaction from the source mode β, H^{[i]} represents a set of multi-scale cross-modal interactions between the target mode α and the source mode β that is as follows:
H^{[i]}={CM_{β→α}(Z_{β→α}^{[i-1]},Z_{α→β}^{j})}j=0,1, . . . ,i−1 (3)
Z_{α→β}^{[0]}=Z_{β}^{[0]} (4)
wherein Z_{β}^{[0]} is a low-level feature of the source mode β, and Z_{β→α}^{[i]} is an output finally through a feedforward-layer fusion:
P_{β→α}^{[i]}=f_{θ}(LN(A_{β→α}^{[i]}+LN(Z_{β→α}^{[i-1]}))) (5)
Z_{β→α}^{[i]}={A_{β→α}^{[i]}+LN(Z_{β→α}^{[i-1]})}+P_{β→α}^{[i]} (6)

6. A computer-readable storage medium having a computer program stored thereon, wherein when the computer program is executed by a processor, the steps of the method according to claim 1 are implemented.
